(19) United States
(12) Patent Application Publication
(10) Pub. No.: US 2026/0006796 A1
(43) Pub. Date: Jan. 1, 2026

(54) MAGNETIC ELEMENT

(71) Applicant: TDK CORPORATION, Tokyo (JP)

(72) Inventors: Yohei SHIOKAWA, Tokyo (JP); Tomoyuki SASAKI, Tokyo (JP); Takeshi SEKI, Sendai-shi (JP); Hiroto MASUDA, Sendai-shi (JP); Koki TAKANASHI, Sendai-shi (JP)

(73) Assignee: TDK CORPORATION, Tokyo (JP)

(21) Appl. No.: 18/836,520

(22) PCT Filed: Feb. 7, 2022
(86) PCT No.: PCT/JP2022/004676

§ 371 Date: May 16, 2025

(51) Int. Cl. H10B 61/00; H10N 50/01; H10N 50/10; H10N 50/85

(52) U.S. Cl. CPC H10B 61/20; H10N 50/01; H10N 50/10; H10N 50/85

(57) ABSTRACT

A magnetic element includes a first ferromagnetic layer, a second ferromagnetic layer, and an intermediate layer, wherein the intermediate layer is between the first ferromagnetic layer and the second ferromagnetic layer, a magnetization of the first ferromagnetic layer and a magnetization of the second ferromagnetic layer have a component that is anti-ferromagnetically coupled, and at least one of the first ferromagnetic layer, the second ferromagnetic layer, and the intermediate layer does not have mirror symmetry and translational symmetry in any one direction within a plane in which each of the layers extends.

### TECHNICAL FIELD

The present invention relates to a magnetic element.

### BACKGROUND ART

Giant magnetoresistance (GMR) effect elements made of a multilayer film of ferromagnetic layers and non-magnetic layers, and tunnel magnetoresistance (TMR) effect elements using an insulating layer (a tunnel barrier layer, a barrier layer) as the non-magnetic layer are known as magnetoresistance effect elements. The magnetoresistance effect element can be applied to magnetic sensors, high-frequency components, magnetic heads, and non-volatile random access memories (MRAMs).

The MRAM is a storage element in which the magnetoresistance effect elements are integrated. The MRAM reads and writes data by utilizing the property that when magnetization directions of two ferromagnetic layers sandwiching a non-magnetic layer in a magnetoresistance effect element change, resistance of the magnetoresistance effect element changes.

### CITATION LIST

### Patent Document

Patent Document 1: JP 2018-26525 A

### SUMMARY OF INVENTION

### Technical Problem

In order to improve the recording stability of data in the magnetoresistance effect element, it is preferable that the magnetization stability of the ferromagnetic layer be high. On the other hand, in order to increase the ease of writing data to the magnetoresistance effect element, it is preferable that the magnetization of the ferromagnetic layer be easily reversible. In other words, the ease of writing and the high recording stability are contradictory. There is a demand for a magnetic element that operates on the basis of a new magnetization control method that is capable of performing writing while the magnetization stability is maintained.

The present invention has been made in consideration of the above circumstances, and an object thereof is to provide a magnetic element that operates on the basis of a new magnetization control method.

### Solution to Problem

In order to solve the above problems, the present invention provides the following means.
(1) A magnetic element according to a first aspect includes a first ferromagnetic layer, a second ferromagnetic layer, and an intermediate layer, wherein the intermediate layer is between the first ferromagnetic layer and the second ferromagnetic layer, a magnetization of the first ferromagnetic layer and a magnetization of the second ferromagnetic layer have a component that is anti-ferromagnetically coupled, and at least one of the first ferromagnetic layer, the second ferromagnetic layer, and the intermediate layer does not have mirror symmetry and translational symmetry in any one direction within a plane in which each of the layers extends.
(2) In the magnetic element according to the aspect, a current may be applied to the first ferromagnetic layer, the second ferromagnetic layer, and the intermediate layer in a direction perpendicular to a lamination direction.
(3) In the magnetic element according to the aspect, the intermediate layer may have a different thickness at a first end that intersects a first direction perpendicular to the lamination direction and a second end that faces the first end.
(4) In the magnetic element according to the aspect, the intermediate layer may have a thickness that gradually changes from the first end to the second end.
(5) In the magnetic element according to the aspect, the intermediate layer may have a step between the first end and the second end.
(6) In the magnetic element according to the aspect, a thickness of a thicker one of the first end and the second end may be 1.3 times or more and 2.5 times or less a thickness of a thinner one of the first end and the second end.
(7) In the magnetic element according to the aspect, the first ferromagnetic layer may have a different thickness at a first end that intersects a first direction perpendicular to a lamination direction and a second end that faces the first end.
(8) In the magnetic element according to the aspect, the first ferromagnetic layer may have a thickness that gradually changes from the first end to the second end.
(9) In the magnetic element according to the aspect, the first ferromagnetic layer may have a step between the first end and the second end.
(10) In the magnetic element according to the aspect, the first ferromagnetic layer may have a different thickness at a third end that intersects a second direction perpendicular to the lamination direction and a fourth end that faces the third end.
(11) In the magnetic element according to the aspect, the first ferromagnetic layer may have a thickness that gradually changes from the third end to the fourth end.
(12) In the magnetic element according to the aspect, the first ferromagnetic layer may have a step between the third end and the fourth end.
(13) In the magnetic element according to the aspect, the intermediate layer may have a different thickness at a first end that intersects a first direction perpendicular to a lamination direction and a second end that faces the first end, and the first ferromagnetic layer may have a different thickness at a third end that intersects the lamination direction and a second direction perpendicular to the first direction, and a fourth end that faces the third end.
(14) In the magnetic element according to the aspect, when an interface between the first ferromagnetic layer and the intermediate layer is a first interface, an interface between the second ferromagnetic layer and the intermediate layer is a second interface, and a surface of the first ferromagnetic layer opposite to the first interface is a third interface, and when an angle between the first interface and the third interface is θ1 and an angle between the second interface and the third interface is θ2, a relationship of θ1<θ2 may be satisfied.
(15) In the magnetic element according to the aspect, the magnetization of the first ferromagnetic layer and the magnetization of the second ferromagnetic layer each may have a component in a lamination direction.
(16) In the magnetic element according to the aspect, the intermediate layer may contain any one selected from a group consisting of Cr, Cu, Mo, Ru, Rh, Re, Ir, Ta, and Pt.
(17) The magnetic element according to the aspect may further include a spin-orbit torque wiring. The spin-orbit torque wiring may be in contact with the first ferromagnetic layer or the second ferromagnetic layer.
(18) In the magnetic element according to the aspect, the spin-orbit torque wiring may contain any one selected from a group consisting of heavy metals having an atomic number of 39 or more, metal oxides, metal nitrides, metal oxynitrides, and topological insulators.
(19) In the magnetic element according to the aspect, a length of the spin-orbit torque wiring in a major axis direction may be longer than a length of the intermediate layer in a major axis direction.
(20) The magnetic element according to the aspect may further include a first wiring and a second wiring. The first wiring and the second wiring may be connected to the spin-orbit torque wiring at positions at which they sandwich the intermediate layer when seen in the lamination direction.

### Advantageous Effects of Invention

The magnetic element and magnetic memory according to the present invention operate with a novel control method.

### BRIEF DESCRIPTION OF DRAWINGS

FIG. 1 is a perspective view of a magnetic element according to a first embodiment.

FIG. 2 is a first cross-sectional view of the magnetic element according to the first embodiment.

FIG. 3 is a second cross-sectional view of the magnetic element according to the first embodiment.

FIG. 4 is a second cross-sectional view of a magnetic element according to a first modified example.

FIG. 5 is a first cross-sectional view of a magnetic element according to a second modified example.

FIG. 6 is a first cross-sectional view of a magnetic element according to a third modified example.

FIG. 7 is a first cross-sectional view of a magnetic element according to a fourth modified example.

FIG. 8 is a schematic diagram for describing a method for manufacturing a magnetic element.

FIG. 9 is a schematic diagram for describing the method for manufacturing a magnetic element.

FIG. 10 is a schematic diagram for describing the method for manufacturing a magnetic element.

FIG. 11 is a schematic diagram for describing the method for manufacturing a magnetic element.

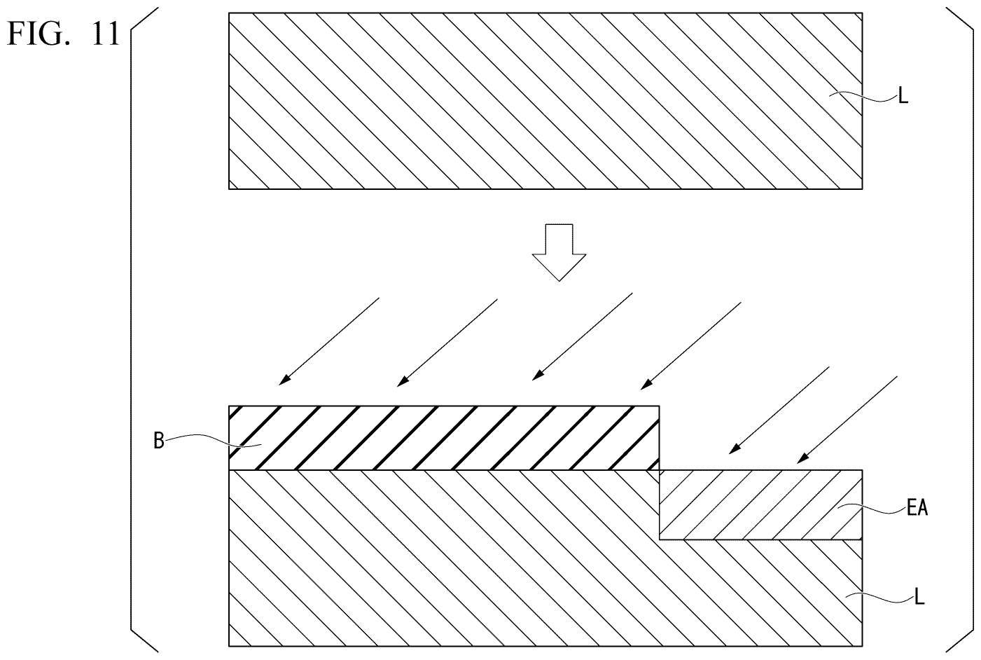

FIG. 12 is a schematic diagram for describing an operation of a magnetic element.

FIG. 13 is a schematic diagram of an experimental system for confirming the operation of the magnetic element.

FIG. 14 shows results of measuring a resistance change of the magnetic element when an external magnetic field is applied to the experimental system shown in FIG. 13.

FIG. 15 is a graph showing a magnetic hysteresis of the magnetic element in the experimental system shown in FIG. 13.

FIG. 16 is a cross-sectional view of a characteristic portion of a magnetic memory according to the first embodiment.

FIG. 17 is a first cross-sectional view of a magnetic element according to a second embodiment.

FIG. 18 is a second cross-sectional view of the magnetic element according to the second embodiment.

FIG. 19 is a cross-sectional view of a characteristic portion of a magnetic memory according to the second embodiment.

FIG. 20 is a first cross-sectional view of a magnetic element according to a third embodiment.

FIG. 21 is a second cross-sectional view of the magnetic element according to the third embodiment.

FIG. 22 is a cross-sectional view of a characteristic portion of a magnetic memory according to the third embodiment.

FIG. 23 is a first cross-sectional view of a magnetic element according to a fourth embodiment.

FIG. 24 is a second cross-sectional view of the magnetic element according to the fourth embodiment.

FIG. 25 is a cross-sectional view of a characteristic portion of a magnetic memory according to the fourth embodiment.

### DESCRIPTION OF EMBODIMENTS

Hereinafter, embodiments will be described in detail with reference to the drawings as appropriate. The drawings used in the following description may show characteristic portions in an enlarged scale for the sake of convenience in order to make the characteristics easier to understand, and the dimensional ratios of each component may differ from the actual ones. The materials, dimensions, and the like exemplified in the following description are merely examples, and the present invention is not limited thereto, and they can be modified as appropriate within the scope of the effects of the present invention.

First, directions will be defined. A direction perpendicular to a reference plane on which magnetic elements are laminated is called a z direction. The z direction is an example of a lamination direction. The reference plane is, for example, a surface of a substrate on which the magnetic elements are laminated. A direction perpendicular to the z direction is defined as an x direction. A direction perpendicular to the x direction is defined as a y direction. The x direction is an example of a first direction or a second direction. The y direction is an example of the first direction or the second direction. Hereinafter, a direction away from the reference plane may be referred to as a +z direction and may be referred to as “up,” and a direction toward a substrate surface may be referred to as a −z direction and may be referred to as “down.” Up and down do not necessarily coincide with a direction in which gravity is applied.

In this specification, “extending in the x direction” means, for example, that a dimension in the x direction is greater than the smallest dimension among dimensions in the x direction, y direction, and z direction. The same applies to extending in other directions. Further, in this specification, the term “connection” is not limited to a physical connection. For example, the term “connection” does not necessarily mean that two layers are in physical contact with each other, but also includes a case in which two layers are connected with another layer sandwiched therebetween. Furthermore, in this specification, the “connection” also includes electrical connection.

### First Embodiment

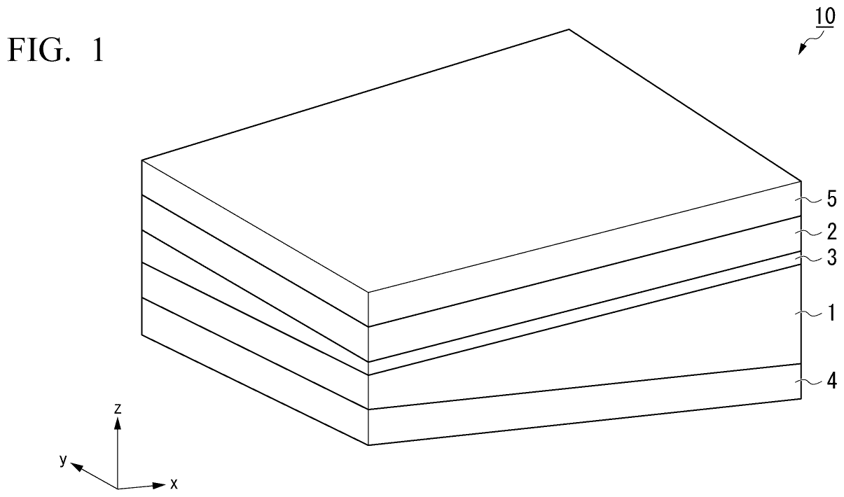

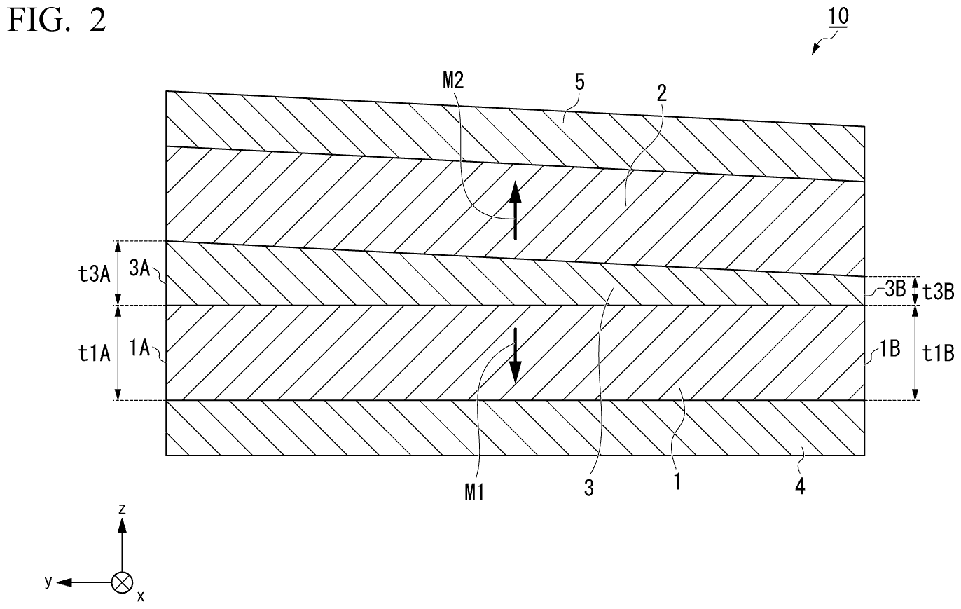

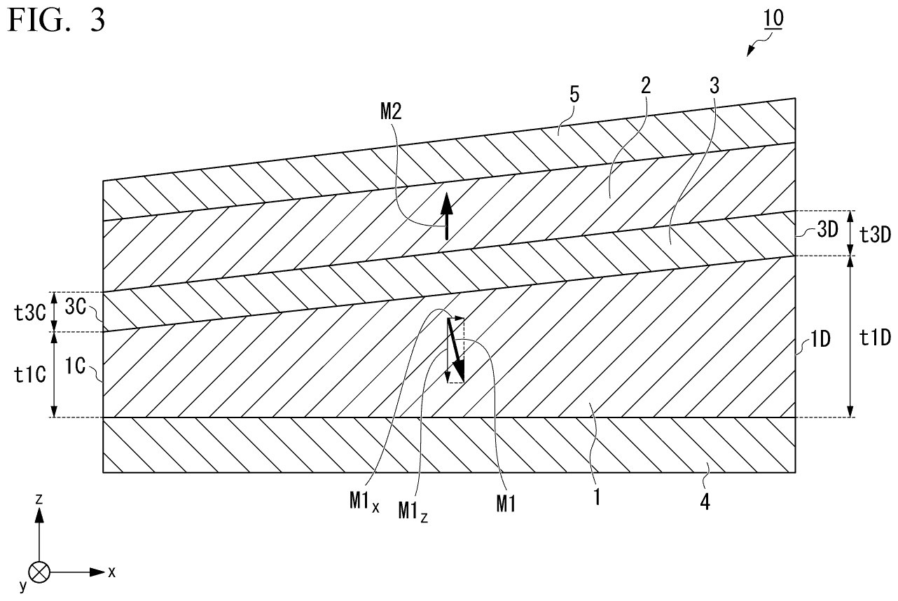

FIG. 1 is a perspective view of a magnetic element 10 according to a first embodiment. FIG. 2 is a cross-sectional view along a yz plane of the magnetic element 10 according to the first embodiment. FIG. 3 is a cross-sectional view along an xz plane of the magnetic element 10 according to the first embodiment. In the example shown in FIGS. 1 to 3, the y direction is the first direction, and the x direction is the second direction.

The magnetic element 10 includes a first ferromagnetic layer 1, a second ferromagnetic layer 2, an intermediate layer 3, a first conductive layer 4, and a second conductive layer 5. The intermediate layer 3 is sandwiched between the first ferromagnetic layer 1 and the second ferromagnetic layer 2. The first conductive layer 4 is on the side of the first ferromagnetic layer 1 opposite to the intermediate layer 3. The second conductive layer 5 is on the side of the second ferromagnetic layer 2 opposite to the intermediate layer 3.

The first ferromagnetic layer 1 does not have mirror symmetry or translational symmetry in any direction within a plane in which the first ferromagnetic layer 1 extends. The plane in which the first ferromagnetic layer 1 extends is a plane in which a lamination surface (a lower surface) of the first ferromagnetic layer extends. The first ferromagnetic layer 1 has a broken symmetry in any direction within the plane in which the first ferromagnetic layer 1 extends.

The first ferromagnetic layer 1 does not have the mirror symmetry and translational symmetry in, for example, the x direction. The first ferromagnetic layer 1 has a broken symmetry in, for example, the x direction. When a mirror is placed at the center of the first ferromagnetic layer 1 in the x direction, an image reflected on the mirror differs from an original image. Also, the first ferromagnetic layer 1 is not symmetric with respect to a translation operation in the x direction.

When the symmetry of the first ferromagnetic layer 1 is broken, variations or continuous changes in magnetic anisotropy or interlayer exchange coupling strength occur in the plane. When the variation in the magnetic anisotropy or interlayer exchange coupling strength occurs in the plane, an effective magnetic field is generated in the plane, and magnetization M1 of the first ferromagnetic layer 1 is inclined from the z direction. As shown in FIG. 3, the magnetization M1 of the first ferromagnetic layer 1 has, for example, a magnetization component M1ₓ in the x direction and a magnetization component M1_{z} in the z direction. The magnetization component M1_{z} in the z direction of the magnetization M1 of the first ferromagnetic layer 1 is larger than the magnetization component M1ₓ in the x direction. A main orientation direction of the magnetization of the first ferromagnetic layer 1 is the z direction.

The first ferromagnetic layer 1 has a different thickness at a third end 1C and a fourth end 1D. Due to the difference in thickness between the third end 1C and the fourth end 1D, the mirror symmetry and translational symmetry in the x direction of the first ferromagnetic layer 1 are broken. The third end 1C is one end of the first ferromagnetic layer 1 in the x direction, and the fourth end 1D is the other end of the first ferromagnetic layer 1 in the x direction. Each of the third end 1C and the fourth end 1D is a side surface of the first ferromagnetic layer 1 that intersects an axis extending in the x direction.

A thickness t1C of the third end 1C is, for example, thinner than a thickness t1D of the fourth end 1D. The thickness t1C of the third end 1C may be thicker than the thickness t1D of the fourth end 1D. The thickness of the thicker one of the third end 1C and the fourth end 1D is, for example, 1.3 times or more and 2.5 times or less the thickness of the thinner one of the third end 1C and the fourth end 1D.

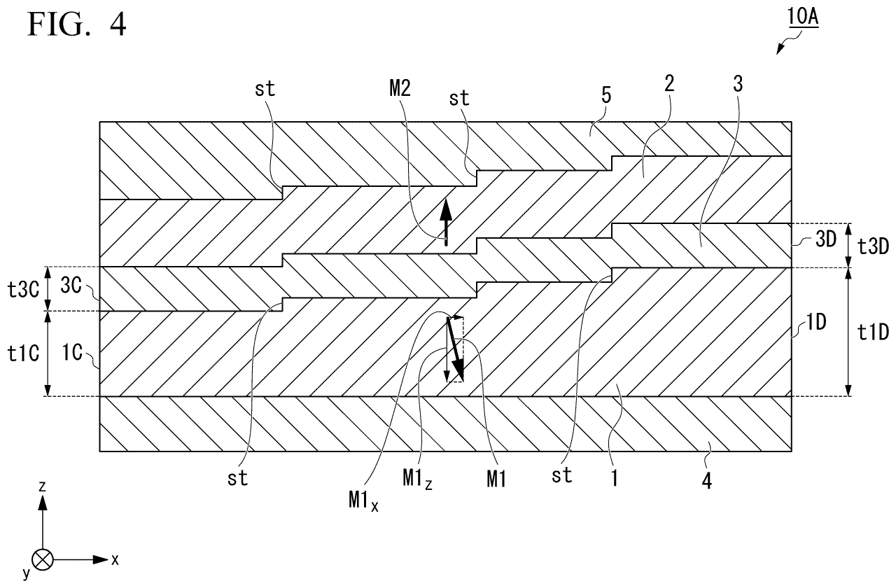

The first ferromagnetic layer 1 has a thickness that gradually changes from the third end 1C to the fourth end 1D. The gradual change means that the thickness continues to increase or decrease. The thickness of the first ferromagnetic layer 1 may change continuously from the third end 1C to the fourth end 1D, or may change while a constant inclination angle is maintained. Further, as in a magnetic element 10A shown in FIG. 4, the first ferromagnetic layer 1 may have a step st between the third end 1C and the fourth end 1D. The step st may be one or more.

The first ferromagnetic layer 1 shown in FIG. 2 has mirror symmetry and translational symmetry in the y direction. A thickness t1A of a first end 1A of the first ferromagnetic layer 1 is equal to a thickness t1B of a second end 1B, for example.

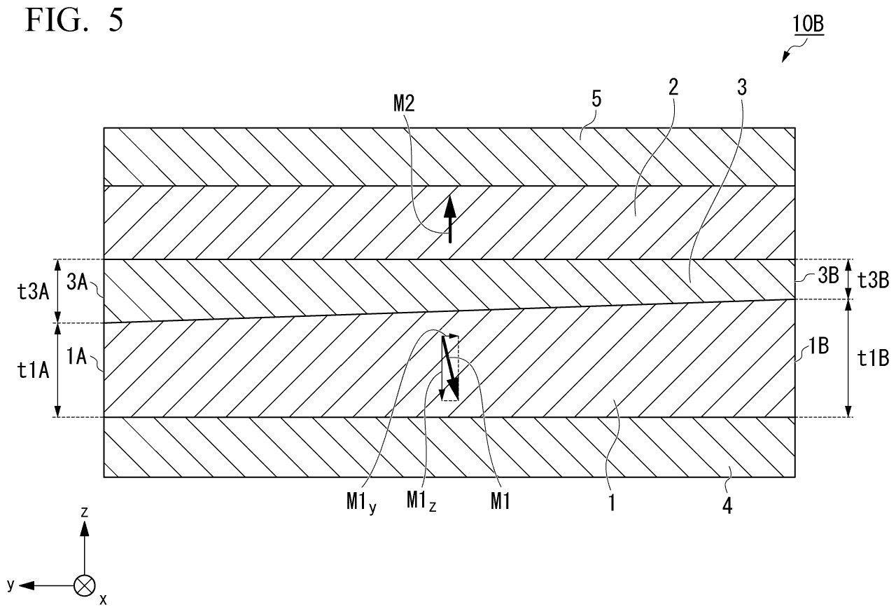

The first ferromagnetic layer 1 does not have to have mirror symmetry and translational symmetry in the y direction, as in a magnetic element 10B shown in FIG. 5. The magnetization M1 of the first ferromagnetic layer 1 shown in FIG. 5 has, for example, a magnetization component M1_{y} in the y direction and a magnetization component M1_{z} in the z direction. The magnetization component M1_{z} in the z direction of the magnetization M1 of the first ferromagnetic layer 1 is larger than the magnetization component M1_{y} in the y direction.

The first ferromagnetic layer 1 shown in FIG. 5 has different thicknesses at the first end 1A and the second end 1B in the y direction. Due to the difference in thickness between the first end 1A and the second end 1B, the mirror symmetry and translational symmetry in the y direction of the first ferromagnetic layer 1 are broken. The first end 1A is one end of the first ferromagnetic layer 1 in the y direction, and the second end 1B is the other end of the first ferromagnetic layer 1 in the y direction. Each of the first end 1A and the second end 1B is a side surface of the first ferromagnetic layer 1 that intersects an axis extending in the y direction.

A thickness t1A of the first end 1A of the first ferromagnetic layer 1 shown in FIG. 5 is smaller than, for example, a thickness t1B of the second end 1B. The thickness t1A of the first end 1A may be thicker than the thickness t1B of the second end 1B. The thickness of the thicker one of the first end 1A and the second end 1B is, for example, 1.3 times or more and 2.5 times or less the thickness of the thinner one of the first end 1A and the second end 1B.

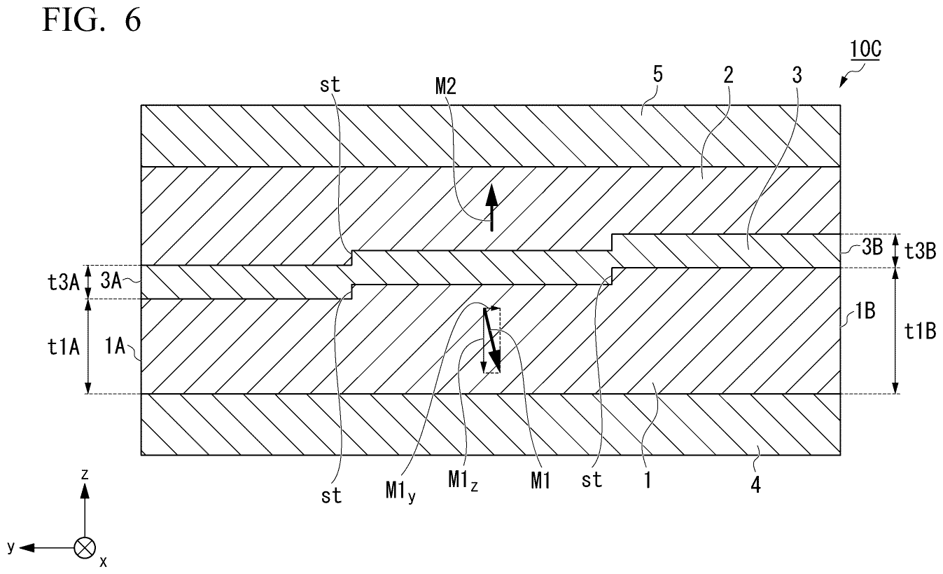

The thickness of the first ferromagnetic layer 1, for example, gradually changes from the first end 1A to the second end 1B. The thickness of the first ferromagnetic layer 1 may change continuously from the first end 1A to the second end 1B, or may change while a constant inclination angle is maintained. Further, as in a magnetic element 10C shown in FIG. 6, the first ferromagnetic layer 1 may have a step st between the first end 1A and the second end 1B. The step st may be one or more.

So far, the example in which the first ferromagnetic layer 1 does not have the mirror symmetry and translational symmetry only in the x direction and the example in which the first ferromagnetic layer 1 does not have the mirror symmetry and translational symmetry in both the x direction and the y direction have been shown, but the first ferromagnetic layer 1 is not limited to the examples. For example, the first ferromagnetic layer 1 may have a configuration in which the first ferromagnetic layer 1 does not have the mirror symmetry and translational symmetry only in the y direction.

Furthermore, changing the thickness of the first ferromagnetic layer 1 is one method for breaking the mirror symmetry and translational symmetry, and the method for breaking the mirror symmetry and translational symmetry is not limited to this example.

For example, a magnitude of the magnetization M1 may be changed within the plane of the first ferromagnetic layer 1. In this case, a demagnetizing field in the plane of the first ferromagnetic layer 1 can be changed, and the mirror symmetry and translational symmetry are broken from the view point of a spatial distribution of a magnetic property.

Furthermore, for example, a magnitude of perpendicular magnetic anisotropy may be changed within the plane of the first ferromagnetic layer 1. When the magnitude of the perpendicular magnetic anisotropy is changed within the plane of the first ferromagnetic layer 1, the mirror symmetry and translational symmetry are broken. The breaking of the mirror symmetry and translational symmetry due to the change in the magnitude of the perpendicular magnetic anisotropy is not limited to a case in which the first ferromagnetic layer 1 is a perpendicular magnetization film having a strong perpendicular magnetic anisotropy. Even when the first ferromagnetic layer 1 is an in-plane magnetic film, an in-plane distribution of the magnetic anisotropy occurs by changing the perpendicular magnetic anisotropy of the first ferromagnetic layer 1, and thus the mirror symmetry and translational symmetry of the first ferromagnetic layer 1 are broken.

The first ferromagnetic layer 1 includes a ferromagnetic material. The ferromagnetic material is, for example, a metal selected from a group consisting of Cr, Mn, Co, Fe, and Ni, an alloy containing one or more of these metals, or an alloy containing these metals and at least one or more of elements B, C, and N. Examples of the ferromagnetic material include Co, Co—Fe, Co—Fe—B, Ni—Fe, a Co—Ho alloy, an Sm—Fe alloy, a Fe—Pt alloy, a Co—Pt alloy, and a CoCrPt alloy.

The first ferromagnetic layer 1 may include a Heusler alloy. The Heusler alloy includes an intermetallic compound having a chemical composition of XYZ or X₂YZ. X is a transition metal element or a noble metal element of the Co, Fe, Ni, or Cu group on the periodic table, Y is a transition metal of the Mn, V, Cr or Ti group or an element species of X, and Z is a typical element of groups III to V. Examples of the Heusler alloy include Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, and the like. The Heusler alloy has a high spin polarization.

The second ferromagnetic layer 2 shown in FIGS. 1 to 3 has mirror symmetry and translational symmetry in all directions within a plane in which the second ferromagnetic layer 2 extends, when a lamination surface of the second ferromagnetic layer 2 (an interface between the intermediate layer 3 and the second ferromagnetic layer 2) is taken as a reference plane. When the lamination surface of the second ferromagnetic layer 2 (the interface between the intermediate layer 3 and the second ferromagnetic layer 2) is taken as a reference plane, the second ferromagnetic layer 2 is uniform. A thickness of the second ferromagnetic layer 2 is, for example, approximately constant. A magnetization M2 of the second ferromagnetic layer 2 is oriented in the z direction.

The second ferromagnetic layer 2 may have the mirror symmetry and translational symmetry in any direction in the plane in which the second ferromagnetic layer 2 extends. The thickness of the second ferromagnetic layer 2 may vary according to a location in the plane, for example. In this case, the magnetization M2 of the second ferromagnetic layer 2 is inclined with respect to the z direction. When the magnetization M1 of the first ferromagnetic layer 1 and the magnetization M2 of the second ferromagnetic layer 2 are both inclined with respect to the z direction, for example, the magnetization M1 and the magnetization M2 may be inclined in the same direction with respect to the z direction. For example, when the magnetization MI has a magnetization component M1ₓ in the +x direction, the magnetization M2 also has a magnetization component in the +x direction. When the inclination directions of the magnetization M1 and the magnetization M2 coincide with each other, the magnetizations tend to rotate.

The second ferromagnetic layer 2 includes a ferromagnetic material. The second ferromagnetic layer 2 may be made of the same material as the first ferromagnetic layer 1.

The magnetization M2 of the second ferromagnetic layer 2 has a component that is anti-ferromagnetically coupled (RKKY-coupled) with the magnetization M1 of the first ferromagnetic layer 1. For example, the magnetization component M1_{z} in the z direction of the first ferromagnetic layer 1 is anti-ferromagnetically coupled to the magnetization M2 of the second ferromagnetic layer 2. Therefore, when the magnetization M1 of the first ferromagnetic layer 1 is reversed, the magnetization M2 of the second ferromagnetic layer 2 is also reversed. The magnetization component M1_{z} in the z direction of the first ferromagnetic layer 1 and the magnetization M2 of the second ferromagnetic layer 2 are oriented in opposite directions.

An average thickness of the second ferromagnetic layer 2 is different from, for example, an average thickness of the first ferromagnetic layer 1. The average thickness of the second ferromagnetic layer 2 is thinner than the average thickness of the first ferromagnetic layer 1, for example. The average thickness of the second ferromagnetic layer 2 may be, for example, thicker than the average thickness of the first ferromagnetic layer 1. The average thickness is an average value of thicknesses measured at ten different points within the plane. The ten different points within the plane are, for example, a geometric center of the layer and nine points equally spaced along a circle surrounding the geometric center. When the second ferromagnetic layer 2 and the first ferromagnetic layer 1 have different average thicknesses, symmetry of the magnetization in the lamination direction is broken, and an effective magnetic field is generated within the plane of the layer.

The intermediate layer 3 is sandwiched between the first ferromagnetic layer 1 and the second ferromagnetic layer 2. The intermediate layer 3 does not have the mirror symmetry or translational symmetry, for example, in any direction within a plane in which the intermediate layer 3 extends. The plane in which the intermediate layer 3 extends is, for example, an interface between the first ferromagnetic layer 1 and the intermediate layer 3. The symmetry of the intermediate layer 3 is broken in any direction within the plane in which the intermediate layer 3 extends.

For example, as shown in FIG. 2, the intermediate layer 3 does not have the mirror symmetry and translational symmetry in the y direction. For example, the symmetry of the intermediate layer 3 in the y direction is broken. When a mirror is placed at the center of the intermediate layer 3 in the y direction, an image reflected in the mirror differs from an original image. Furthermore, the intermediate layer 3 is not symmetric with respect to a translation operation in the y direction.

When the symmetry of the intermediate layer 3 is broken, the strength of the anti-ferromagnetic coupling between the first ferromagnetic layer 1 and the second ferromagnetic layer 2 varies within the plane. For example, the strength of the anti-ferromagnetic coupling acting between the first ferromagnetic layer 1 and the second ferromagnetic layer 2 differs between a position moved in the +y direction from the center in the y direction in FIG. 2 and a position moved in the −y direction therefrom. That is, the breaking of symmetry in the intermediate layer 3 creates a difference in the strength of anti-ferromagnetic coupling between the first ferromagnetic layer 1 and the second ferromagnetic layer 2, and generates an effective magnetic field in the plane of the first ferromagnetic layer 1 and the second ferromagnetic layer 2.

The intermediate layer 3 has a different thickness at a first end 3A and a second end 3B. The difference in thickness between the first end 3A and the second end 3B breaks the mirror symmetry and translational symmetry of the intermediate layer 3 in the y direction. The first end 3A is one end of the intermediate layer 3 in the y direction, and the second end 3B is the other end of the intermediate layer 3 in the y direction. Each of the first end 3A and the second end 3B is a side surface of the intermediate layer 3 that intersects an axis extending in the y direction.

A thickness t3A of the first end 3A is, for example, thicker than a thickness t3B of the second end 3B. The thickness t3A of the first end 3A may be thinner than the thickness t3B of the second end 3B. The thickness of the thicker one of the first end 3A and the second end 3B is, for example, 1.3 times or more and 2.5 times or less the thickness of the thinner one of the first end 3A and the second end 3B.

The intermediate layer 3 preferably includes a portion having a film thickness that maximizes the anti-ferromagnetic coupling. The film thickness that maximizes the anti-ferromagnetic coupling varies according to the material, for example, 0.45 nm to 0.50 nm for Ru, and 0.40 nm to 0.54 nm for Ir. When the portion of the film thickness that maximizes the anti-ferromagnetic coupling is between the thickness t3A of the first end 3A and the thickness t3B of the second end 3B, the variation in the strength of the anti-ferromagnetic coupling will be large, and the effective magnetic field generated by the breaking of the mirror symmetry and translational symmetry will become large.

The thickness of the intermediate layer 3 changes gradually, for example, from the first end 3A to the second end 3B. The thickness of the intermediate layer 3 may change continuously from the first end 3A to the second end 3B, or may change while a constant inclination angle is maintained. Further, as in a magnetic element 10C shown in FIG. 6, the intermediate layer 3 may have a step st between the first end 3A and the second end 3B. The step st may be one or more.

The intermediate layer 3 shown in FIG. 3 has the mirror symmetry and translational symmetry in an xz cross section when the lamination surface of the intermediate layer 3 (the interface between the intermediate layer 3 and the first ferromagnetic layer 1) is taken as a reference plane. A thickness t3C of a third end 3C of the intermediate layer 3 is equal to a thickness t3D of a fourth end 3D, for example.

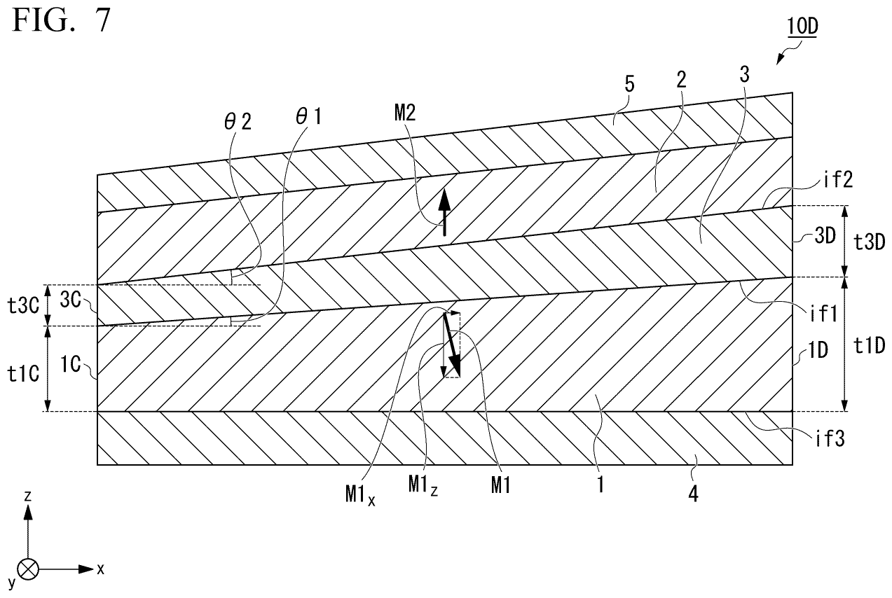

The intermediate layer 3 does not have to have the mirror symmetry and translational symmetry in the xz cross section, as in a magnetic element 10D shown in FIG. 7.

The intermediate layer 3 shown in FIG. 7 has a different thickness at a third end 3C and a fourth end 3D in the x direction. The difference in thickness between the third end 3C and the fourth end 3D breaks the mirror symmetry and translational symmetry in the xz cross section of the intermediate layer 3. The third end 3C is one end of the intermediate layer 3 in the x direction, and the fourth end 3D is the other end of the intermediate layer 3 in the x direction. Each of the third end 3C and the fourth end 3D is a side surface of the intermediate layer 3 that intersects an axis extending in the x direction.

A thickness t3C of the third end 3C of the intermediate layer 3 shown in FIG. 7 is thinner than, for example, a thickness t3D of the fourth end 3D. The thickness t3C of the third end 3C may be thicker than the thickness t3D of the fourth end 3D. The thickness of the thicker one of the third end 3C and the fourth end 3D is, for example, 1.3 times or more and 2.5 times or less the thickness of the thinner one of the third end 3C and the fourth end 3D.

The thickness of the intermediate layer 3 may gradually change from the third end 3C to the fourth end 3D. The thickness of the intermediate layer 3 may change continuously from the third end 3C to the fourth end 3D, or may change while a constant inclination angle is maintained. Further, as in the magnetic element 10A shown in FIG. 4, the intermediate layer 3 may have a step st between the third end 3C and the fourth end 3D. The step st may be one or more.

Also, as shown in FIG. 7, when an interface formed between the first ferromagnetic layer 1 and the intermediate layer 3 is a first interface if1, an interface formed between the second ferromagnetic layer 2 and the intermediate layer 3 is a second interface if2, an interface of the first ferromagnetic layer 1 on the side opposite to the intermediate layer 3 is a third interface if3, an angle between the first interface if1 and the third interface if3 is θ1 and an angle between the second interface if2 and the third interface if3 is θ2, it is preferable that the relationship between the angles satisfies θ1<θ2. When this relationship is satisfied, the mirror symmetry and translational symmetry of the entire magnetic element 10 can be further broken.

FIG. 7 shows the relationship between θ1 and θ2 in the x direction, but θ1 and θ2 are angles between surfaces and are not limited to the x direction. For example, when the first interface if1 is inclined in the x direction with respect to the third interface if3, and the second interface if2 is inclined in the y direction with respect to the third interface if3, θ1 is an angle in the x direction, and θ2 is an angle in the y direction.

The intermediate layer 3 is a non-magnetic material and contains, for example, any one selected from a group consisting of Cr, Cu, Mo, Ru, Rh, Re, Ir, Ta, and Pt. The intermediate layer 3 is, for example, any metal selected from the group consisting of Cr, Cu, Mo, Ru, Rh, Re, Ir, Ta, and Pt, or an alloy thereof.

The first conductive layer 4 and the second conductive layer 5 are wirings for applying a current to a laminate consisting of the first ferromagnetic layer 1, the intermediate layer 3 and the second ferromagnetic layer 2. The first conductive layer 4 and the second conductive layer 5 are conductors. When data is read out, a current is applied in an in-plane direction of the laminate using the first conductive layer 4 or the second conductive layer 5.

Next, a description will be given of a method for manufacturing the magnetic element 10. The method for manufacturing the magnetic element 10 includes a step of laminating each of layers and a step of processing each of the layers into a predetermined shape. The layers can be laminated by, for example, a sputtering method, an ion beam method, a vapor deposition method, or the like. The step of processing a shape of each of the layers can be performed by, for example, photolithography, or the like.

There are several methods for inclining an upper surface L1 of a layer L with respect to a lower surface L2 (a reference surface, a lamination surface). The processing of the layer L can be applied to any of the first ferromagnetic layer 1, the second ferromagnetic layer 2, and the intermediate layer 3 described above.

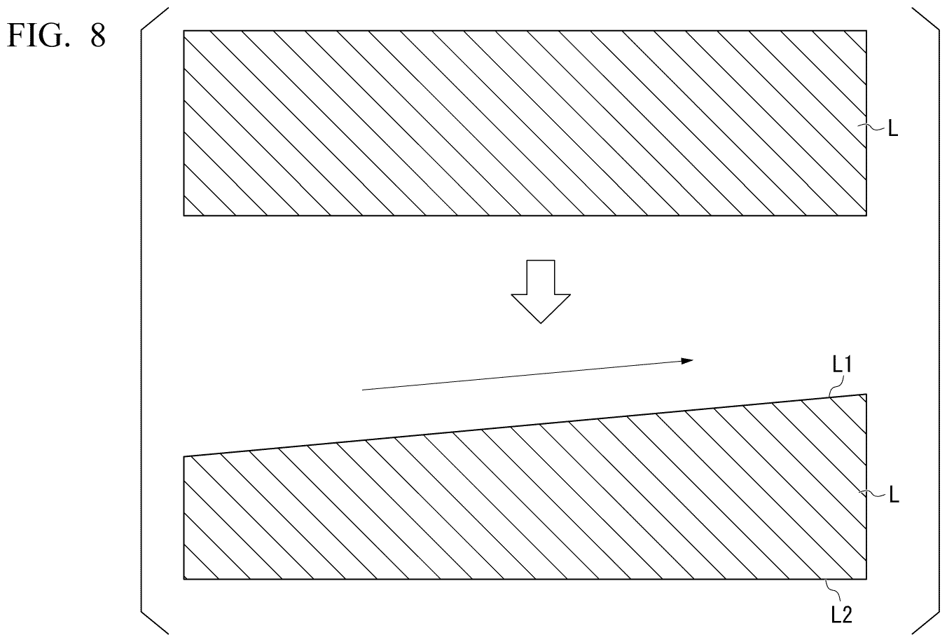

For example, as shown in FIG. 8, the laminated layer L is polished in one direction. The polishing is performed by, for example, chemical mechanical polishing (CMP). Since a large force is applied at an initial stage when a polishing pad and an object to be polished come into contact with each other, a first end which is an end on which the polishing begins is polished more than a second end. As a result, the upper surface L1 is inclined with respect to the lower surface L2.

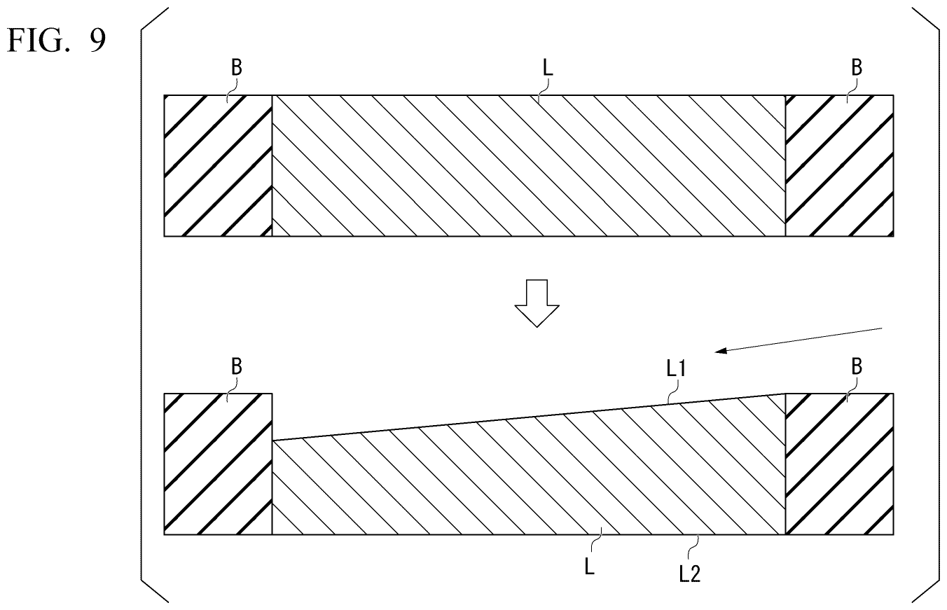

Further, for example, as shown in FIG. 9, the laminated layer L is anisotropically etched. After the layer L is laminated, a block layer B is formed around the layer L. The block layer B has a higher hardness than the layer L. The anisotropic etching is performed in a direction inclined with respect to the lamination direction. The anisotropic etching is performed by, for example, ion milling, reactive ion etching (RIE), or the like. During the anisotropic etching, the etching of a portion of the layer L that is shaded by the block layer B proceeds slower than the other portions due to a shadowing effect. As a result, the upper surface L1 is inclined with respect to the lower surface L2.

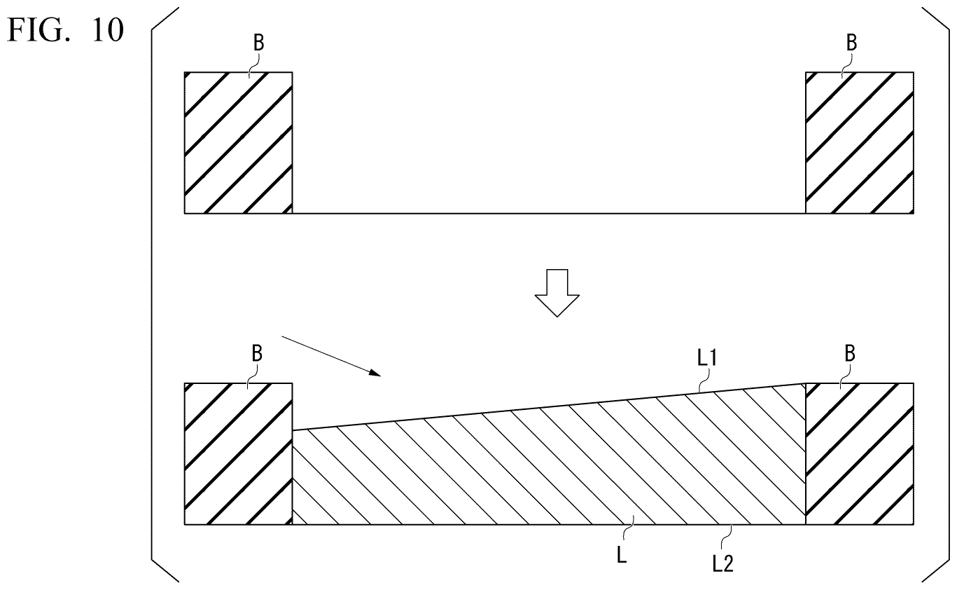

Further, for example, as shown in FIG. 10, the layer L may be deposited anisotropically. First, the block layer B is formed around a portion on which the layer Lis to be formed. Then, film formation is performed in a direction inclined with respect to a vertical direction of the lamination surface. The film formation is performed by, for example, a sputtering method, a vapor deposition method, a laser ablation method, or an ion beam deposition (IBD) method. In the portion that is shaded by the block layer B, the film formation does not progress easily due to the shadowing effect, and the upper surface L1 is inclined with respect to the lower surface L2.

There are also several methods for distributing the magnetization or magnetic anisotropy of the layer L within a film plane. This processing of the layer L can be applied to both the first ferromagnetic layer 1 and the second ferromagnetic layer 2 described above.

For example, the block layer B is formed to cover a part of the upper surface L1 of the layer L, and then anisotropic etching is performed in the vertical direction. By using a weak etching energy that does not etch the layer L or by performing the etching for a short time, it is possible to weaken the magnetic anisotropy of the layer L in an exposed region that is not covered by the block layer B and to reduce the magnitude of magnetization. Furthermore, by using an etching energy that can sufficiently etch the layer L or by performing the etching for a long period of time, it is possible to provide a step on the surface of the layer L.

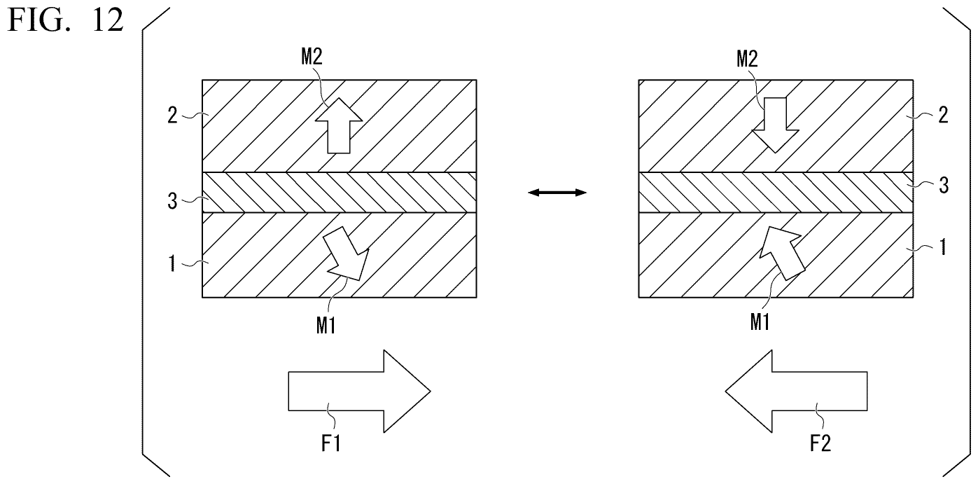

Next, a description will be given of an operation of the magnetic element 10. FIG. 12 is a schematic diagram for describing the operation of the magnetic element 10. The magnetic element 10 exhibits the anomalous Hall effect (AHE).

The magnetization M1 of the first ferromagnetic layer 1 is reversed when external forces F1 and F2 are applied in predetermined directions in the xy plane. The magnetization M2 of the second ferromagnetic layer 2 is anti-ferromagnetically coupled with the magnetization M1 of the first ferromagnetic layer 1, and is thus reversed when the magnetization M1 of the first ferromagnetic layer 1 is reversed.

When the magnetization M1 of the first ferromagnetic layer 1 is oriented in the z direction, the magnetization does not stably reverse even when the external forces F1 and F2 are applied in predetermined directions in the xy plane. This is because the external forces F1 and F2 exert a force to incline the magnetization M1 by 90° but do not promote any further rotation.

In contrast, the first ferromagnetic layer 1 according to the first embodiment is inclined with respect to the z direction. Therefore, as shown in the left diagram of FIG. 12, when the external force F1 is applied in a direction in which the magnetization M1 is inclined, the magnetization rotation of the magnetization M1 is assisted, and the magnetization M1 is stably reversed. Further, in the left diagram of FIG. 12, when the external force F2 is applied in a direction opposite to the inclination direction of the magnetization M1, the magnetization rotation of the magnetization M1 is hindered, making it difficult for the magnetization to be reversed. Similarly, in the right diagram of FIG. 12, when the external force F2 is applied in the direction in which the magnetization M1 is inclined, the magnetization rotation of the magnetization M1 is assisted, and when the external force F1 is applied in the direction opposite to the inclination direction of the magnetization M1, the magnetization rotation of the magnetization M1 is hindered, making it difficult for the magnetization to be reversed.

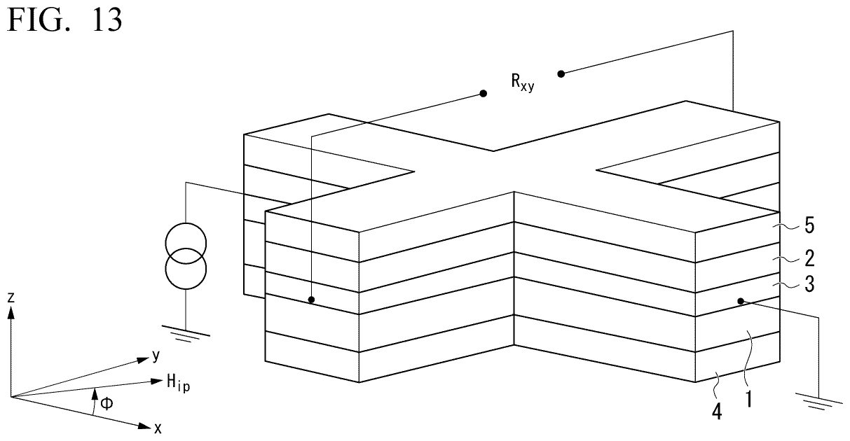

FIG. 13 is a schematic diagram of an experiment system for evaluating the operation of the magnetic element 10 according to the first embodiment. Although the illustration in FIG. 13 is simplified, the film configuration of each of layers is the same as that in FIGS. 1 to 3. That is, the first ferromagnetic layer 1 does not have the mirror symmetry and translational symmetry in the x direction, and the intermediate layer 3 does not have the mirror symmetry or translational symmetry in the y direction.

While a current is applied in the x direction of the magnetic element 10 having perpendicular magnetization, an external magnetic field Hᵢₚ was applied as the external forces F1 and F2 that promote the magnetization rotation. The in-plane external magnetic field Hᵢₚ was applied in a direction inclined by 45° from the x direction toward the y direction (φ=45°).

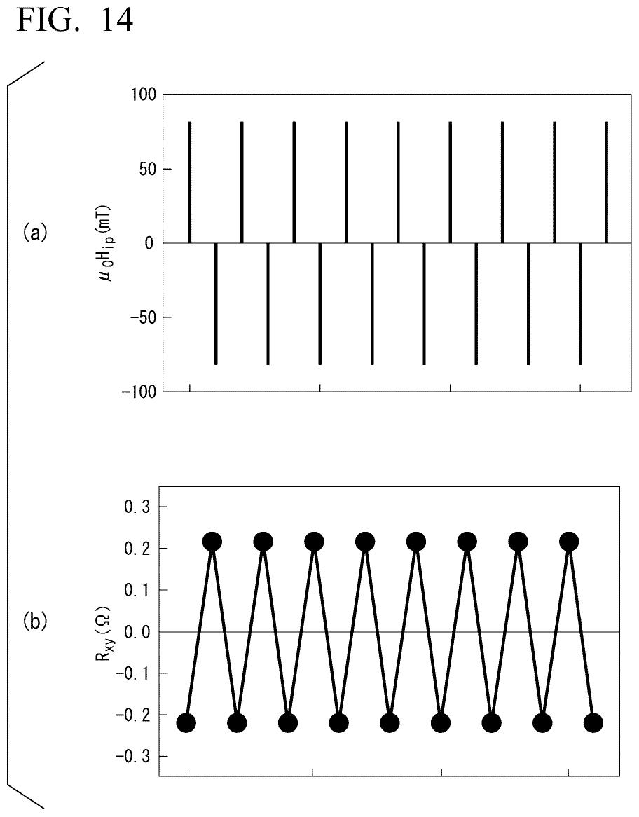

FIG. 14 shows results of measuring a resistance change of the magnetic element 10 when the in-plane external magnetic field Hᵢₚ is applied to the experimental system shown in FIG. 13. FIG. 14(a) shows the magnitude of the in-plane external magnetic field, which was applied alternately at +75 mT and −75 mT. FIG. 14(b) shows a Hall resistance value R_{xy} in the xy plane of the magnetic element 10. As shown in FIG. 14, when the in-plane external magnetic field Hᵢₚ was changed, the resistance value R_{xy} of the magnetic element 10 changed accordingly. That is, the resistance value R_{xy} of the magnetic element 10 is switched by applying the external forces F1 and F2 in the xy plane of the magnetic element 10.

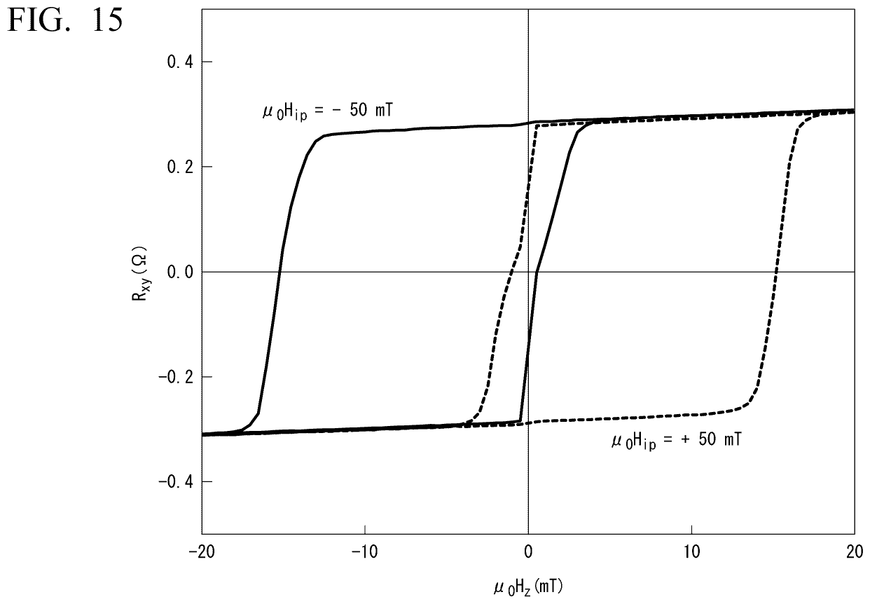

FIG. 15 is a graph showing a magnetic hysteresis of the magnetic element 10. FIG. 15 shows results when the in-plane external magnetic field Hᵢₚ of +50 mT and −50mT was applied in a direction inclined by 45° from the x direction toward the y direction (φ=45°) in the experimental system shown in FIG. 13. A vertical axis represents the Hall resistance value R_{xy} of the magnetic element 10, and a horizontal axis represents the magnetic field strength of the magnetic field H_{z} applied in the z direction.

When the magnitude of the magnetic field H_{z} applied in the z direction is increased, the magnetization M1 of the first ferromagnetic layer 1 is reversed. When a large magnetic field H_{z} (about 15 mT) is applied in the +z direction while an in-plane external magnetic field Hᵢₚ of +50 mT is applied in the in-plane direction, the resistance value R_{xy} changes from −0.3Ω to 0.3Ω. In contrast, when a small magnetic field H_{z} (about 0 mT) is applied in the +z direction while an in-plane external magnetic field Hᵢₚ of −50 mT is applied in the in-plane direction, the resistance value R_{xy} changes from −0.3Ω to 0.3Ω.

The state in which the in-plane external magnetic field Hᵢₚ of −50 mT is applied corresponds to the state in which the external force F2 is applied in the right diagram of FIG. 12, and the state in which the in-plane external magnetic field Hᵢₚ of +50 mT is applied corresponds to the state in which the external force F1 is applied in the right diagram of FIG. 12. In the right diagram of FIG. 12, when the external force F2 is applied, the magnetization reversal of the magnetization M1 is assisted, whereas when the external force F1 is applied, the magnetization reversal of the magnetization M1 is inhibited (not assisted).

Furthermore, as shown in FIG. 15, a hysteresis curve of the magnetic element 10 is shifted while a shape is maintained even when the in-plane external magnetic field Hᵢₚ is applied. In other words, a coercivity of each of the first ferromagnetic layer 1 and the second ferromagnetic layer 2 remains unchanged. In the magnetic element 10, the resistance value R_{xy} is changed while the magnetization stability is maintained. The resistance value R_{xy} is converted into a signal recorded by the magnetic element 10.

As described above, the magnetic element 10 according to the first embodiment operates on the basis of a new magnetization control method in which writing is performed by applying a magnetic field in the xy plane to a perpendicular magnetization film oriented approximately in the z direction. Furthermore, the magnetic element 10 can perform writing while the coercivity of each of the first ferromagnetic layer 1 and the second ferromagnetic layer is maintained, and thus has excellent stability in retaining data against heat and external magnetic fields. This magnetic element can be applied, for example, to a memory for storing information, or to a magnetic sensor that responds only to an in-plane magnetic field.

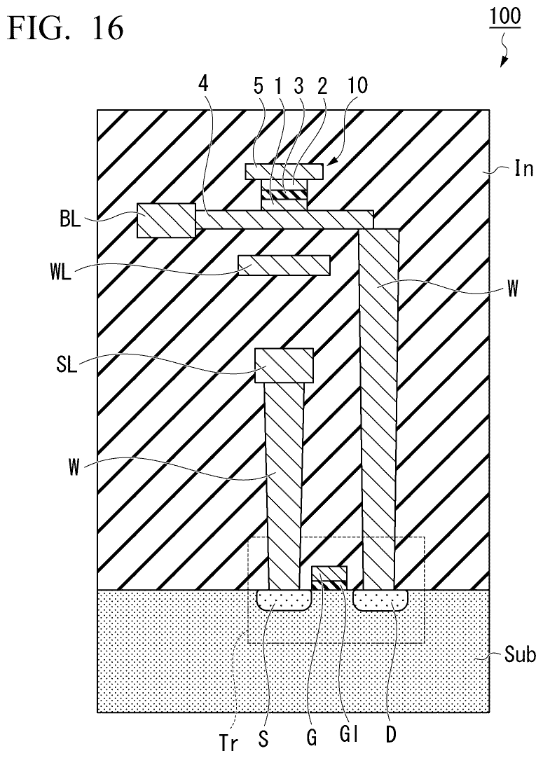

The magnetic element 10 according to the first embodiment can be applied to, for example, a magnetic memory. FIG. 16 is a cross-sectional view of a characteristic portion of the magnetic memory 100.

The magnetic memory 100 includes a transistor Tr, a magnetic element 10, a source line SL, a bit line BL, a word line WL, and a wiring W. The magnetic memory 100 is formed on a substrate Sub and is covered with an insulating layer In.

The insulating layer In is an insulating layer that provides insulation between wirings in a multilayer wiring structure and between elements. The insulating layer In is made of, for example, silicon oxide (SiOx), silicon nitride (SiNx), silicon carbide (SiC), chromium nitride, silicon carbonitride (SiCN), silicon oxynitride (SiON), aluminum oxide (Al₂O₃), zirconium oxide (ZrOx), magnesium oxide (MgO), aluminum nitride (AlN), or the like.

The word line WL is a wiring used when data is written to the magnetic element 10. The word line WL extends from the front side to the back side of the drawing.

The source line SL and the bit line BL are wirings used when data is read from the magnetic element 10.

The transistor Tr switches electrical connection between the source line SL and the bit line BL. The transistor Tr can be replaced with an element that utilizes a phase change of a crystal layer, such as an ovonic threshold switch (OTS), an element that utilizes a change in band structure, such as a metal-insulator transition (MIT) switch, an element that utilizes a breakdown voltage, such as a Zener diode or an avalanche diode, and an element of which conductivity changes with a change in atomic position.

The wiring W connects the transistor Tr to the magnetic element 10 or each of wirings.

When a current flows through the word line WL, an external magnetic field is applied in the plane of the magnetic element 10. When an external magnetic field is applied to the magnetic element 10, the magnetizations of the first ferromagnetic layer 1 and the second ferromagnetic layer 2 are reversed, and the resistance value of the magnetic element 10 changes. For example, data is recorded in the magnetic element 10 by setting the resistance value of the magnetic element 10 in a large state to “1” and in a small state to “0.” The data recorded in the magnetic element 10 can be controlled by a direction of the current flowing through the word line WL.

When a current flows between the source line SL and the bit line BL, the resistance value of the magnetic element 10 can be read.

A plurality of magnetic memories 100 are arranged in a matrix to form a magnetic recording array.

### Second Embodiment

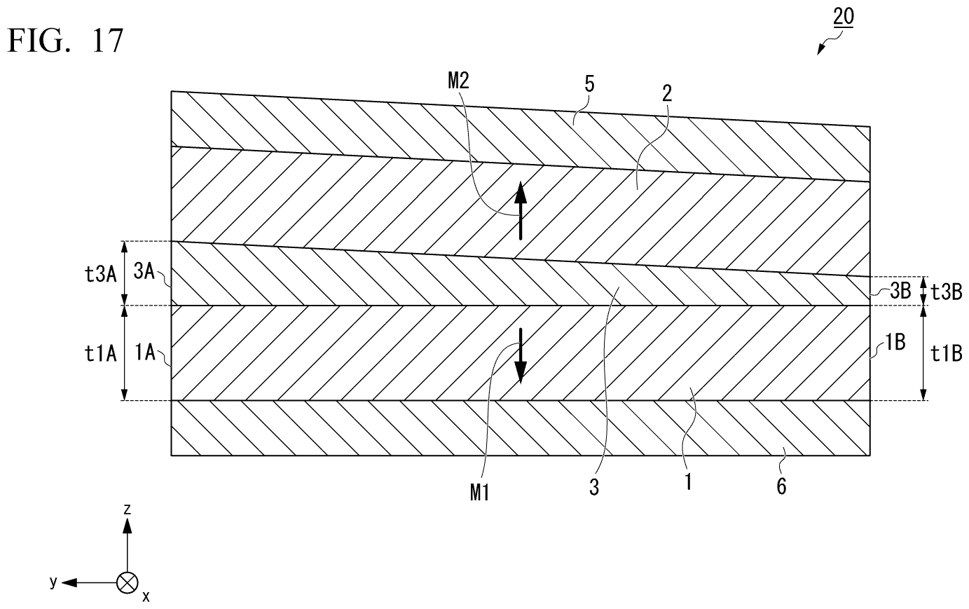

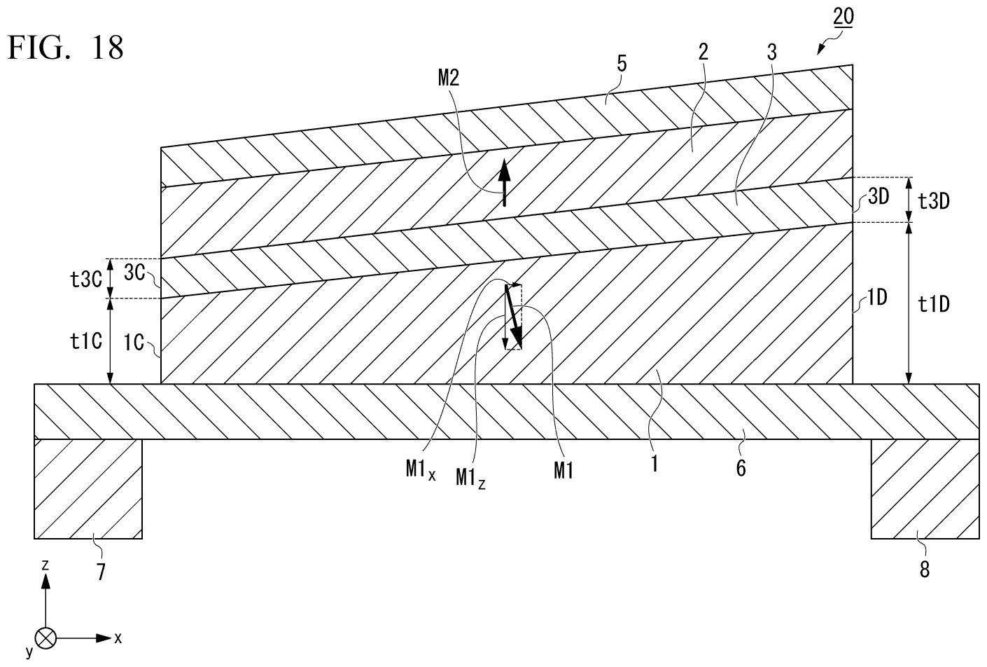

FIG. 17 is a cross-sectional view along a yz plane of the magnetic element 20 according to a second embodiment. FIG. 18 is a cross-sectional view along an xz plane of the magnetic element 20 according to the second embodiment. The magnetic element 20 is different from the magnetic element 10 according to the first embodiment in that the first conductive layer 4 is replaced with a spin-orbit torque wiring 6 and in that the magnetic element 20 has a first wiring 7 and a second wiring 8.

The spin-orbit torque wiring 6 extends in the x direction, for example, such that a length in the x direction is longer than a length in the y direction when seen in the z direction. A length of the spin-orbit torque wiring 6 in the x direction is, for example, longer than a length of the intermediate layer 3 in the x direction. The length of the spin-orbit torque wiring 6 in the x direction may be, for example, longer than a length of each of the first ferromagnetic layer 1 and the second ferromagnetic layer 2 in the x direction.

The first wiring 7 and the second wiring 8 are connected to the spin-orbit torque wiring 6. The first wiring 7 and the second wiring 8 are connected to the spin-orbit torque wiring 6 at positions at which they sandwich the first ferromagnetic layer 1 when seen in the z direction.

The spin-orbit torque wiring 6 generates a spin current by the spin Hall effect when a current flows, and injects spins into the first ferromagnetic layer 1. The spin-orbit torque wiring 6 applies, for example, a spin-orbit torque (SOT) to the magnetization M1 of the first ferromagnetic layer 1 sufficient to reverse the magnetization M1 of the first ferromagnetic layer 1.

The spin Hall effect is a phenomenon in which, when a current flows, a spin current is induced in a direction perpendicular to a direction of the current due to a spin-orbit interaction. The spin Hall effect is similar to the conventional Hall effect in that a direction of movement (motion) in which charges (electrons) move can be bent. In the conventional Hall effect, a direction of motion of a charged particle moving in a magnetic field is bent by a Lorentz force. In contrast, the spin Hall effect allows the direction of movement of spins to be bent simply by the movement of electrons (the flow of current) even in the absence of a magnetic field.

For example, when a current flows through the spin-orbit torque wiring 6, first spins oriented in one direction and second spins oriented in a direction opposite to the first spins are bent by the spin Hall effect in a direction perpendicular to a direction in which the current flows. For example, the first spins oriented in the −y direction are bent from the x direction, which is the direction of travel, to the +z direction, and the second spins oriented in the +y direction are bent from the x direction, which is the direction of travel, to the −z direction.

In a non-magnetic material (a material that is not ferromagnetic), the number of electrons of the first spins generated by the spin Hall effect is equal to the number of electrons of the second spins. That is, the number of electrons of the first spins in the +z direction is equal to the number of electrons of the second spins in the −z direction. The first spins and the second spins flow in a direction that eliminates uneven distribution of spins. In the movement of the first spins and the second spins in the z direction, since the flows of charges cancel each other out, an amount of current is zero. A spin current that does not involve a current is particularly called a pure spin current.

When the flow of electrons of the first spins is represented as J_{↑}, the flow of electrons of the second spins is represented as J_{↓}, and the spin current as Jₛ, then Jₛ=J_{↑}−J_{↓}. The spin current Jₛ is generated in the z direction. The first spins are injected from the spin-orbit torque wiring 6 into the first ferromagnetic layer 1.

The spin-orbit torque wiring 6 includes any one of a metal, an alloy, an intermetallic compound, a metal boride, a metal carbide, a metal silicide, a metal phosphide, and a metal nitride that have a function of generating a spin current by the spin Hall effect when a current I flows. The spin-orbit torque wiring 6 includes, for example, any one selected from a group consisting of heavy metals having an atomic number of 39 or more, metal oxides, metal nitrides, metal oxynitrides, and topological insulators.

The spin-orbit torque wiring 6 contains, for example, a non-magnetic heavy metal as a main component. The heavy metal means a metal having a specific gravity equal to or greater than that of yttrium (Y). The non-magnetic heavy metal is, for example, a non-magnetic metal having d electrons or f electrons in the outermost shell and a large atomic number of 39 or more. The spin-orbit torque wiring 6 is made of, for example, Hf, Ta, or W. The non-magnetic heavy metal has a spin-orbit interaction stronger than other metals. The spin Hall effect is generated by the spin-orbit interaction, spins tend to be unevenly distributed in the spin-orbit torque wiring 6, and thus a spin current Jₛ is easily generated.

The spin-orbit torque wiring 6 may further contain a magnetic metal. The magnetic metal is a ferromagnetic metal or an anti-ferromagnetic metal. A trace amount of magnetic metal contained in a non-magnetic material becomes a scattering factor of spins. The trace amount is, for example, 3% or less of the total molar ratio of the elements constituting the spin-orbit torque wiring 6. When the spins are scattered by the magnetic metal, the spin-orbit interaction is enhanced, and the efficiency of generating a spin current with respect to a current increases.

The spin-orbit torque wiring 6 may include a topological insulator. The topological insulator is a material in which the interior of the material is an insulator or a highly resistive material, but a spin-polarized metallic state occurs on a surface thereof. In the topological insulator, an internal magnetic field is generated due to the spin-orbit interaction. In the topological insulator, a new topological phase emerges due to an effect of the spin-orbit interaction even in the absence of an external magnetic field. The topological insulator can generate a pure spin current with high efficiency due to a strong spin-orbit interaction and breaking of inversion symmetry at an edge.

Examples of the topological insulator include SnTe, Bi_{1.5}Sb_{0.5}Te_{1.7}Se_{1.3}, TlBiSe₂, Bi₂Te₃, Bi₁₋ₓSbₓ, (Bi₁₋ₓSbₓ)₂Te₃, and the like. The topological insulator is capable of generating a spin current with high efficiency.

The spins injected from the spin-orbit torque wiring 6 to the first ferromagnetic layer 1 apply a spin-orbit torque to the magnetization M1 of the first ferromagnetic layer 1. The spin-orbit torque corresponds to the external forces F1 and F2 shown in FIG. 12. That is, the magnetic element 20 according to the second embodiment uses the spin-orbit torque as the external forces F1 and F2, instead of an external magnetic field. A direction of the spin-orbit torque applied to the magnetization M1 can be controlled by a direction of the current flowing through the spin-orbit torque wiring 6.

The magnetic element 20 according to the second embodiment operates on the same principle as the magnetic element 10 according to the first embodiment, except that the external force applied to the first ferromagnetic layer 1 is changed from an external magnetic field to a torque due to spin injection.

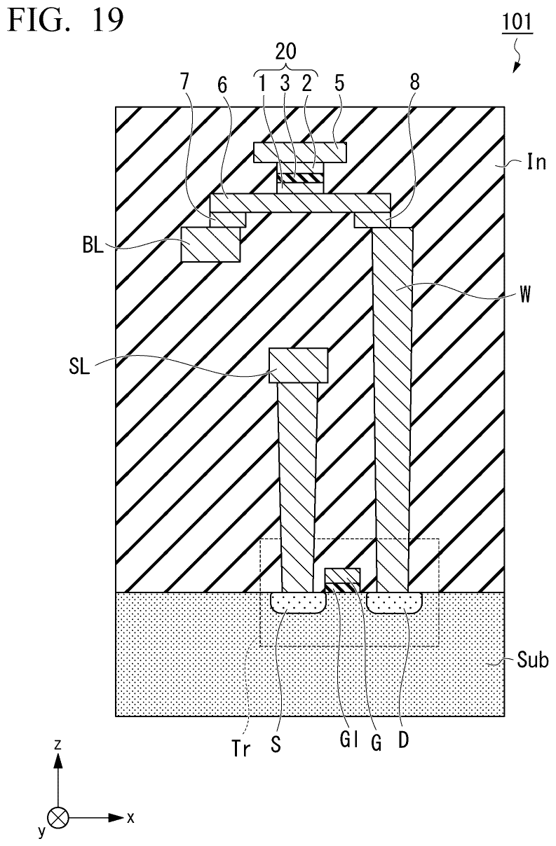

The magnetic element 20 according to the second embodiment can also be applied to a magnetic memory. FIG. 19 is a cross-sectional view of a characteristic portion of the magnetic memory 101.

The magnetic memory 101 includes a magnetic element 20, a transistor Tr, a source line SL, a bit line BL, and a wiring W. The magnetic memory 101 is formed on a substrate Sub and is covered with an insulating layer In.

When data is written to the magnetic element 20, the source line SL and the bit line BL are electrically connected to each other, and a current is applied to the spin-orbit torque wiring 6. Spins are injected from the spin-orbit torque wiring 6 into the first ferromagnetic layer 1, and data is written to the magnetic element 20.

When data is read from the magnetic element 20, the source line SL and the bit line BL are also electrically connected to each other, and a current is applied in the in-plane direction of the magnetic element 20. A reading current is smaller than a writing current. The spins injected into the first ferromagnetic layer 1 by the reading current do not reverse the magnetization M1 of the first ferromagnetic layer 1.

A plurality of magnetic memories 101 are arranged in a matrix to form a magnetic recording array.

### Third Embodiment

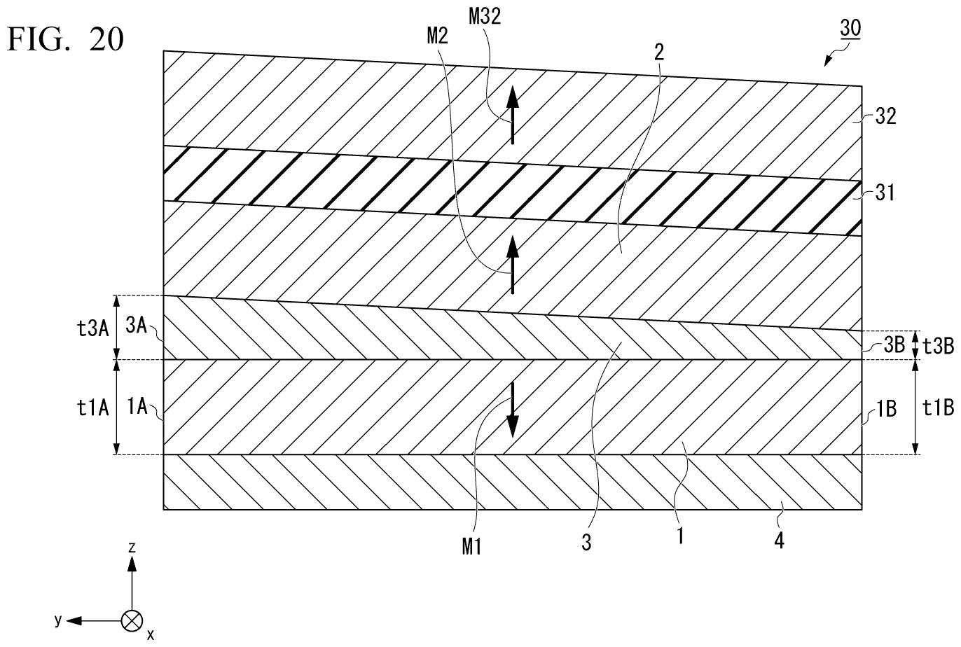

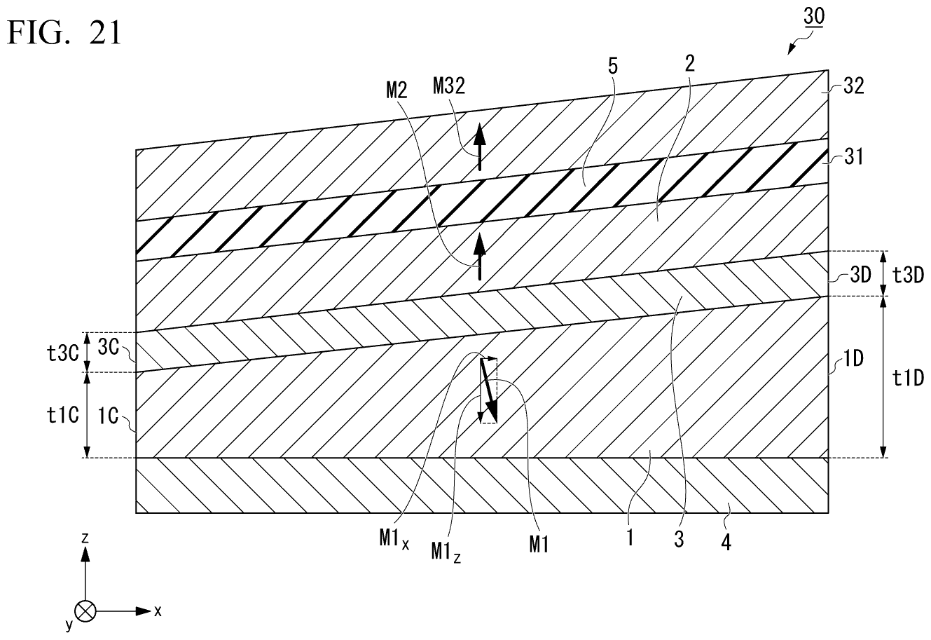

FIG. 20 is a cross-sectional view along a yz plane of a magnetic element 30 according to a third embodiment. FIG. 21 is a cross-sectional view along an xz plane of the magnetic element 30 according to the third embodiment. The magnetic element 30 differs from the magnetic element 10 according to the first embodiment in that it further includes a non-magnetic layer 31 and a third ferromagnetic layer 32.

In the magnetic elements 10 and 20, an example has been shown in which data is recorded using a change in resistance value due to the anomalous Hall effect (AHE), but the magnetic element 30 records data using a giant magnetoresistance effect (GMR) or a tunneling magnetoresistance effect (TMR).

The non-magnetic layer 31 includes a non-magnetic material. When the non-magnetic layer 31 is an insulator, the magnetic element 30 exhibits the tunneling magnetoresistance effect. When the non-magnetic layer 31 is a conductor or a semiconductor, the magnetic element 30 exhibits the giant magnetoresistance effect.

When the non-magnetic layer 31 is an insulator (when it is a tunnel barrier layer), examples thereof that can be used include Al₂O₃, SiO₂, MgO, MgAl₂O₄, and the like. In addition to them, materials in which part of Al, Si, or Mg is replaced with Zn, Be, or the like can also be used. Among them, MgO and MgAl₂O₄ are materials that can realize coherent tunneling, and thus spins can be injected efficiently. When the non-magnetic layer 31 is made of a metal, a material thereof may be Cu, Au, Ag, or the like. Furthermore, when the non-magnetic layer 31 is made of a semiconductor, a material thereof may be Si, Ge, CuInSe₂, CuGaSe₂, Cu(In,Ga)Se₂, or the like.

When a predetermined external force is applied, an orientation direction of magnetization of the third ferromagnetic layer 32 is less likely to change than that of the first ferromagnetic layer 1 and the second ferromagnetic layer 2. The third ferromagnetic layer 32 is referred to as a magnetization fixed layer or a magnetization reference layer. The magnetization of the first ferromagnetic layer 1 is reversed by the external forces F1 and F2, and the magnetization of the second ferromagnetic layer 2 is reversed in accordance with the reversal of the magnetization of the first ferromagnetic layer 1. The first ferromagnetic layer 1 and the second ferromagnetic layer 2 are referred to as a magnetization free layer. The magnetic element 30 has a resistance value that changes according to a difference in relative angle between the magnetization M2 of the second ferromagnetic layer 2 and the magnetization M32 of the third ferromagnetic layer 32.

The magnetic element 30 records data by a change in resistance value in the lamination direction. For example, when the magnetization M2 of the second ferromagnetic layer 2 and the magnetization M32 of the third ferromagnetic layer 32 are parallel, it is designated as “0,” and when the magnetization M2 of the second ferromagnetic layer 2 and the magnetization M32 of the third ferromagnetic layer 32 are anti-parallel to each other, it is designated as “1.”

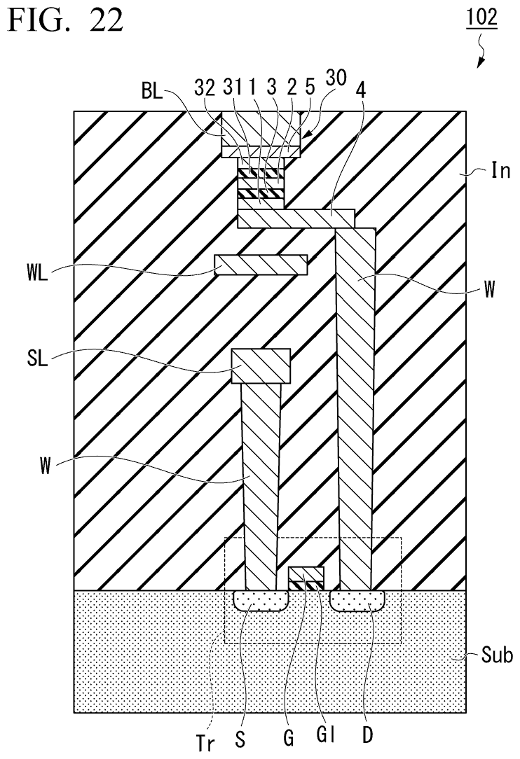

The magnetic element 30 according to the third embodiment can also be applied to a magnetic memory. FIG. 22 is a cross-sectional view of a characteristic portion of the magnetic memory 102.

The magnetic memory 102 differs from the magnetic memory 100 in the position of the bit line BL. The bit line BL is connected to the second conductive layer 5, for example.

When a current flows through the word line WL, an external magnetic field is applied in the plane of the magnetic element 30. When an external magnetic field is applied to the magnetic element 30, the magnetization of each of the first ferromagnetic layer 1 and the second ferromagnetic layer 2 is reversed, and the resistance value of the magnetic element 30 in the lamination direction changes. The data recorded in the magnetic element 30 can be controlled by a direction of the current flowing through the word line WL.

The resistance value in the lamination direction of the magnetic element 30 can be obtained from Ohm's law by passing a current between the source line SL and the bit line BL. By reading the resistance value of the magnetic element 30, the data recorded in the magnetic element 30 is read.

A plurality of magnetic memories 102 are arranged in a matrix to form a magnetic recording array.

### Fourth Embodiment

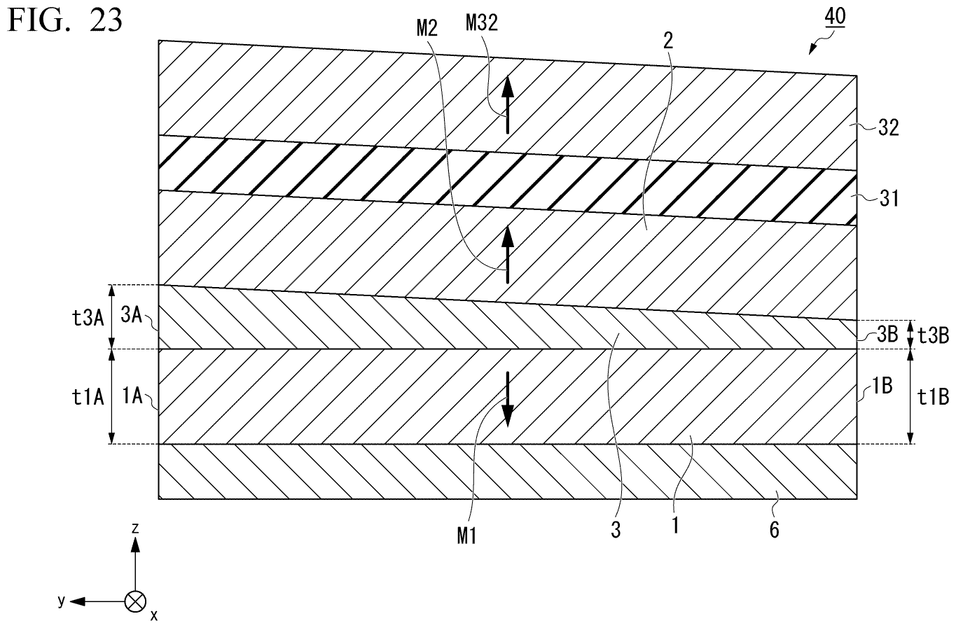

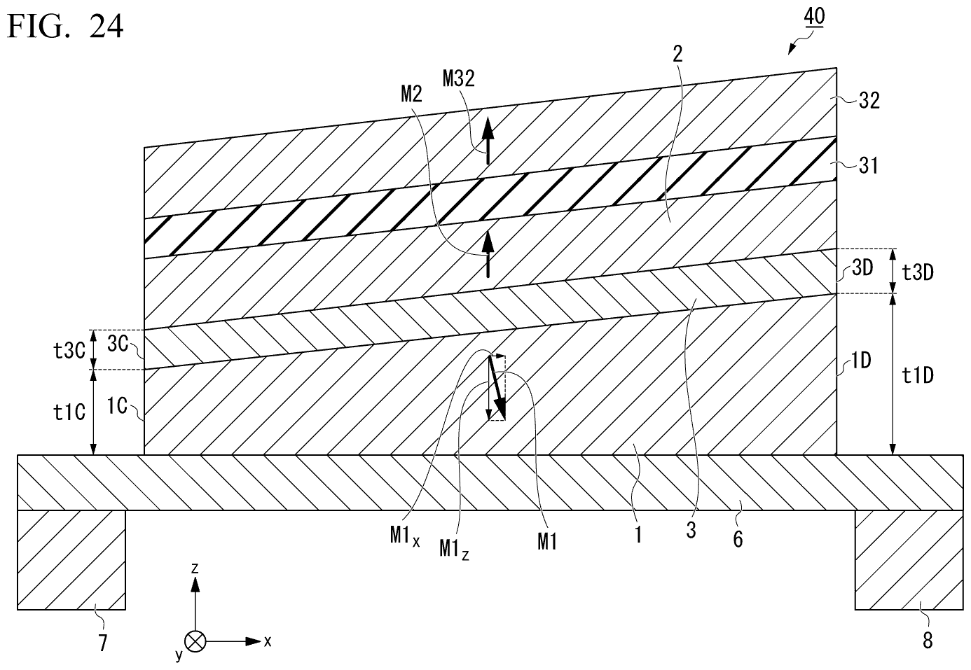

FIG. 23 is a cross section of the magnetic element 40 according to a fourth embodiment taken along a yz plane. FIG. 24 is a cross section of the magnetic element 40 according to the fourth embodiment taken along an xz plane. The magnetic element 40 differs from the magnetic element 20 according to the second embodiment in that it further includes a non-magnetic layer 31 and a third ferromagnetic layer 32.

In the magnetic elements 10 and 20, an example has been shown in which data is recorded using a change in resistance value due to the anomalous Hall effect (AHE), but the magnetic element 40 records data using the giant magnetoresistance effect (GMR) or the tunneling magnetoresistance effect (TMR). The configurations of the non-magnetic layer 31 and the third ferromagnetic layer 32 are similar to those in the third embodiment.

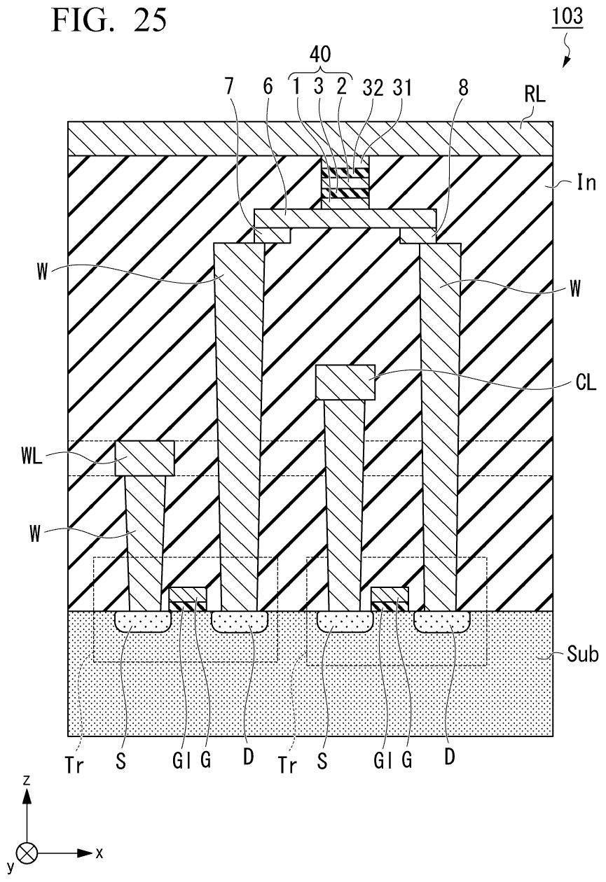

The magnetic element 40 according to the fourth embodiment can also be applied to a magnetic memory. FIG. 25 is a cross-sectional view of a characteristic portion of the magnetic memory 103.

The magnetic memory 103 includes a magnetic element 40, a plurality of transistors Tr, word lines WL, read lines RL, common lines CL, and wiring W.

When data is written to the magnetic element 40, the word line WL and the common line CL are electrically connected to each other, and a current is applied to the spin-orbit torque wiring 6. Spins are injected from the spin-orbit torque wiring 6 into the first ferromagnetic layer 1, and data is written to the magnetic element 40.

When data is read from the magnetic element 40, the read line RL and the common line CL are electrically connected to each other, and a current is applied in the lamination direction of the magnetic element 40. The resistance value in the lamination direction of the magnetic element 40 can be obtained from Ohm's law by passing a current between the lead line RL and the common line CL. By reading the resistance value of the magnetic element 40, the data recorded in the magnetic element 40 is read.

A plurality of magnetic memories 103 are arranged in a matrix to form a magnetic recording array.

Although several examples of the magnetic elements according to the first to fourth embodiments have been shown above, additions, omissions, substitutions, and other modifications of the configuration are possible without departing from the spirit of the present invention. For example, the modified example of the magnetic element according to the first embodiment can be applied to the other embodiments. In addition, an external magnetic field and a spin-orbit torque may be used in combination as the external forces F1 and F2.

### REFERENCE SIGNS LIST

1 First ferromagnetic layer
1A, 3A First end
1B, 3B Second end
1C, 3C Third end
1D, 3D Fourth end
2 Second ferromagnetic layer
3 Intermediate layer
4 First conductive layer
5 Second conductive layer
6 Spin-orbit torque wiring
7 First wiring
8 Second wiring
10, 10A, 10B, 10C, 10D, 20, 30, 40 Magnetic element
31 Non-magnetic layer
32 Third ferromagnetic layer
100, 101, 102, 103 Magnetic memory
M1, M2, M32 Magnetization
M1ₓ, M1_{y}, M1_{z} Magnetization component
st Step

1. A magnetic element comprising:
a first ferromagnetic layer, a second ferromagnetic layer, and an intermediate layer,
wherein the intermediate layer is between the first ferromagnetic layer and the second ferromagnetic layer,
a magnetization of the first ferromagnetic layer and a magnetization of the second ferromagnetic layer have a component that is anti-ferromagnetically coupled, and
at least one of the first ferromagnetic layer, the second ferromagnetic layer, and the intermediate layer does not have mirror symmetry and translational symmetry in any one direction within a plane in which each of the layers extends.

2. The magnetic element according to claim 1, wherein a current is applied to the first ferromagnetic layer, the second ferromagnetic layer, and the intermediate layer in a direction perpendicular to a lamination direction.

3. The magnetic element according to claim 1, wherein the intermediate layer has a different thickness at a first end that intersects a first direction perpendicular to the lamination direction and a second end that faces the first end.

4. The magnetic element according to claim 3, wherein the intermediate layer has a thickness that gradually changes from the first end to the second end.

5. The magnetic element according to claim 3, wherein the intermediate layer has a step between the first end and the second end.

6. The magnetic element according to claim 3, wherein a thickness of a thicker one of the first end and the second end is 1.3 times or more and 2.5 times or less a thickness of a thinner one of the first end and the second end.

7. The magnetic element according to claim 1, wherein the first ferromagnetic layer has a different thickness at a first end that intersects a first direction perpendicular to a lamination direction and a second end that faces the first end.

8. The magnetic element according to claim 7, wherein the first ferromagnetic layer has a thickness that gradually changes from the first end to the second end.

9. The magnetic element according to claim 7, wherein the first ferromagnetic layer has a step between the first end and the second end.

10. The magnetic element according to claim 1, wherein the first ferromagnetic layer has a different thickness at a third end that intersects a second direction perpendicular to the lamination direction and a fourth end that faces the third end.

11. The magnetic element according to claim 10, wherein the first ferromagnetic layer has a thickness that gradually changes from the third end to the fourth end.

12. The magnetic element according to claim 10, wherein the first ferromagnetic layer has a step between the third end and the fourth end.

13. The magnetic element according to claim 1, wherein the intermediate layer has a different thickness at a first end that intersects a first direction perpendicular to a lamination direction and a second end that faces the first end, and
the first ferromagnetic layer has a different thickness at a third end that intersects the lamination direction and a second direction perpendicular to the first direction, and a fourth end that faces the third end.

14. The magnetic element according to claim 1, wherein when an interface between the first ferromagnetic layer and the intermediate layer is a first interface, an interface between the second ferromagnetic layer and the intermediate layer is a second interface, and a surface of the first ferromagnetic layer opposite to the first interface is a third interface, and
when an angle between the first interface and the third interface is θ1 and an angle between the second interface and the third interface is θ2, a relationship of θ1<θ2 is satisfied.

15. The magnetic element according to claim 1, wherein the magnetization of the first ferromagnetic layer and the magnetization of the second ferromagnetic layer each have a component in a lamination direction.

16. The magnetic element according to claim 1, wherein the intermediate layer contains any one selected from a group consisting of Cr, Cu, Mo, Ru, Rh, Re, Ir, Ta, and Pt.

17. The magnetic element according to claim 1, further comprising a spin-orbit torque wiring,
wherein the spin-orbit torque wiring is in contact with the first ferromagnetic layer or the second ferromagnetic layer.

18. The magnetic element according to claim 17, wherein the spin-orbit torque wiring contains any one selected from a group consisting of heavy metals having an atomic number of 39 or more, metal oxides, metal nitrides, metal oxynitrides, and topological insulators.

19. The magnetic element according to claim 17, wherein a length of the spin-orbit torque wiring in a major axis direction is longer than a length of the intermediate layer in a major axis direction.

20. The magnetic element according to claim 17, further comprising a first wiring and a second wiring,
wherein the first wiring and the second wiring are connected to the spin-orbit torque wiring at positions at which they sandwich the intermediate layer when seen in the lamination direction.
